(19) United States
(12) Patent Application Publication
(10) Pub. No.: US 2013/0009308 A1
(43) Pub. Date: Jan. 10, 2013

(54) SEMICONDUCTOR STACK PACKAGE APPARATUS

(76) Inventor: Heung-Kyu KWON, Seongnam-si (KR)

(21) Appl. No.: 13/530,578

(22) Filed: Jun. 22, 2012

(30) Foreign Application Priority Data
Jul. 6, 2011 (KR) 10-2011-0066870

(51) Int. Cl. H01L 23/498

(52) U.S. Cl. 257/738; 257/777; 257/E23.069; 257/E23.068

(57) ABSTRACT

A semiconductor stack package apparatus includes an upper semiconductor package and a lower semiconductor package. The upper semiconductor chip includes a chip pad, an upper substrate including a substrate pad formed on a top surface of the upper substrate and an upper ball land formed on a bottom surface of the upper substrate and attached to an intermediate solder ball, and a wire connecting the chip pad and the substrate pad. The lower semiconductor package includes a lower semiconductor chip including a bump, and a lower substrate including a bump land formed on a top surface of the lower substrate in an area corresponding to the bump, an intermediate ball land formed on the top surface of the lower substrate in an area corresponding to the intermediate solder ball, and a lower ball land formed on a bottom surface of the lower substrate and attached to a lower solder ball.

### CROSS-REFERENCE TO RELATED APPLICATIONS

This application claims priority under 35 U.S.C. §119 to Korean Patent Application No. 10-2011-0066870, filed on Jul. 6, 2011, the disclosure of which is incorporated by reference herein in its entirety.

### TECHNICAL FIELD

Exemplary embodiments of the inventive concept relate to a semiconductor stack package apparatus, and more particularly, to a thin package-on-package (POP) type semiconductor stack package apparatus.

### DISCUSSION OF THE RELATED ART

A semiconductor package apparatus may be manufactured by die bonding semiconductor chips on a surface of a lead frame or a printed circuit board (PCB), electrically connecting leads of the lead frame or terminals of the PCB to the semiconductor chips via a wire bonding or soldering operation, and covering the semiconductor chips with an insulating encapsulation member.

Various technologies may be utilized to decrease the size of the semiconductor package apparatus. For example, package-on-package (POP) technology may be used to stack packages, system-on-chip (SOC) technology may be used to integrate various functions on one chip, and a system-in-package technology may be used to integrate semiconductor chips (e.g., a memory chip and a control chip) that perform a plurality of different functions into one package. As the size of the semiconductor package apparatus decreases, the wiring layout between chips in the package may become complex, resulting in electrical interference and decreased performance.

### SUMMARY

According to an exemplary embodiment of the inventive concept, a semiconductor stack package apparatus includes an upper semiconductor package including an upper semiconductor chip having a chip pad formed on its active surface, an upper substrate supporting the upper semiconductor chip, having a substrate pad formed on its top surface in a corresponding direction to the chip pad, and having an intermediate solder ball attached on an upper ball land formed on its bottom surface, a wire electrically connecting the chip pad and the substrate pad, and an encapsulation member protecting the active surface of the upper semiconductor chip and the wire by surrounding the active surface and the wire. The semiconductor stack package apparatus further includes a lower semiconductor package including a lower semiconductor chip having a bump formed on its active surface, and a lower substrate supporting the lower semiconductor chip, has and having a bump land corresponding to the bump, and an intermediate ball land corresponding to the intermediate solder ball formed on its top surface, and having a lower solder ball attached to a lower ball land formed on its bottom surface.

The upper semiconductor chip may include a semiconductor chip in which all chip pads are integrated and formed on one end.

The upper semiconductor chip may include a first semiconductor chip in which all chip pads are integrated and formed on a first end in a first direction, a second semiconductor chip in which all chip pads are integrated and formed on a second end in a second direction, a third semiconductor chip in which all chip pads are integrated and formed on a third end in a third direction, and a fourth semiconductor chip in which all chip pads are integrated and formed on a fourth end in a fourth direction.

The first semiconductor chip may be mounted on the top surface of the upper substrate, the second semiconductor chip may be stacked on a top surface of the first semiconductor chip, the third semiconductor chip may be stacked on a top surface of the second semiconductor chip, and the fourth semiconductor chip may be stacked on a top surface of the third semiconductor chip.

The first semiconductor chip and the third semiconductor chip may be mounted on the top surface of the upper substrate, and the second semiconductor and the fourth semiconductor chip may be stacked on the top surfaces of the first semiconductor chip and the third semiconductor chip.

The second semiconductor chip may be stacked on the first semiconductor chip with the first direction and the second direction being substantially the same, and the fourth semiconductor chip may be formed on the third semiconductor chip with the third direction and the fourth direction being substantially the same, and forming an angle of about 180° or about 90° with respect to the first and second directions.

The upper semiconductor chip may include a semiconductor chip in which all chip pads are integrated and formed on two ends, the upper semiconductor chip may include a first semiconductor chip in which all chip pads are integrated and formed on a first end and a third end, a second semiconductor chip in which all chip pads are integrated and formed on a second end and a fourth end, a third semiconductor chip in which all chip pads are integrated and formed on a third end and a first end, and a fourth semiconductor chip in which all chip pads are integrated and formed on a fourth end and a second end. The first semiconductor chip and the third semiconductor chip may be mounted on the top surface of an upper substrate, the second semiconductor chip and the fourth semiconductor chip may be mounted on top surfaces of the first semiconductor chip and the third semiconductor chip, and an inner wire bonding space may be formed between the first semiconductor chip and the third semiconductor chip and between the second semiconductor chip and the fourth semiconductor chip.

The upper semiconductor chip may include a first semiconductor chip in which all chip pads are integrated and formed on a first end in a first direction, a second semiconductor chip in which all chip pads are integrated and formed on a second end in a second direction and a fourth end in a fourth direction, a third semiconductor chip in which all chip pads are integrated and formed on a third end in a third direction, and a fourth semiconductor chip in which all chip pads are integrated and formed on a fourth end in a fourth direction and a second end in a second direction. The second semiconductor chip may be stacked on the first semiconductor chip with the first direction and the second direction being substantially the same, and the fourth semiconductor chip may be stacked on the third semiconductor chip with the third direction and the fourth direction being substantially the same and forming an angle of about 180° with respect to the first and second directions. An inner wire bonding space may be formed between the second semiconductor chip and the fourth semiconductor chip.

The upper semiconductor chip may include a first semiconductor chip in which all chip pads are integrated and formed on a first end in a first direction, a second semiconductor chip in which all chip pads are integrated and formed on a second end in a second direction and a fourth end in a fourth direction, a third semiconductor chip in which all chip pads are integrated and formed on a third end in a third direction, and a fourth semiconductor chip in which all chip pads are integrated and formed on a fourth end in a fourth direction and a second end in a second direction. The second semiconductor chip may be stacked on the first semiconductor chip with the first direction and the second direction being substantially the same, and the fourth semiconductor chip may be stacked on the third semiconductor chip with the third direction and the fourth direction being substantially the same and forming an angle of about 90° with respect to the first and second directions.

The upper semiconductor chip may include a semiconductor chip in which DQ chip pads are integrated on one end and CA chip pads are integrated on an opposing end, and may include a first semiconductor chip in which the DQ chip pads are integrated on a first end and the CA chip pads are integrated on a third end, a second semiconductor chip in which the DQ chip pads are integrated on a second end and the CA chip pads are integrated on a fourth end, a third semiconductor chip in which the DQ chip pads are integrated on a third end and the CA chip pads are integrated on a first end, and a fourth semiconductor chip in which the DQ chip pads are integrated on a fourth end and the CA chip pads are integrated on a second end. The first semiconductor chip may be mounted on the top surface of the upper substrate, the second semiconductor chip may be stacked on a top surface of the first semiconductor chip, the third semiconductor chip may be stacked on a top surface of the second semiconductor chip, and the fourth semiconductor chip may be stacked on a top surface of the third semiconductor chip. The first semiconductor chip and the second semiconductor chip may form an angle of about 90° or about 180°, the second semiconductor chip and the third semiconductor chip may form an angle of about 90°, and the third semiconductor chip and the fourth semiconductor chip may form an angle of about 90° or about 180°.

The upper substrate or the lower substrate may include a first redistribution layer electrically connected to the substrate pad or the intermediate ball land, a second redistribution layer electrically connected to the first redistribution layer and electrically connected to the upper ball land or the lower ball land, and a metal core layer formed between the first redistribution layer and the second redistribution layer.

The upper semiconductor chip may be a memory chip, and the lower semiconductor chip may be a control chip, and the bump land of the lower substrate may correspond to the bump of the lower semiconductor chip and may include a first interface unit that is electrically connected to a first semiconductor chip of the upper semiconductor chip and that is disposed on a first end of a lower semiconductor chip corresponding region, a second interface unit that is electrically connected to a second semiconductor chip of the upper semiconductor chip and that is disposed on a second end of the lower semiconductor chip corresponding region, a third interface unit that is electrically connected to a third semiconductor chip of the upper semiconductor chip and that is disposed on a third end of the lower semiconductor chip corresponding region, and a fourth interface unit that is electrically connected to a fourth semiconductor chip of the upper semiconductor chip and that is disposed on a fourth end of the lower semiconductor chip corresponding region.

The bump land of the lower substrate may correspond to the bump of the lower semiconductor chip and may include a first interface unit that is electrically connected to a first semiconductor chip of the upper semiconductor chip and that is disposed on a first end of a lower semiconductor chip corresponding region, a fourth interface unit that is electrically connected to a fourth semiconductor chip of the upper semiconductor chip and that is disposed together with the first interface unit on the first end of the lower semiconductor chip corresponding region, a second interface unit that is electrically connected to a second semiconductor chip of the upper semiconductor chip and that is disposed on a second end of the lower semiconductor chip corresponding region, and a third interface unit that is electrically connected to a third semiconductor chip of the upper semiconductor chip and that is disposed together with the second interface unit on the second end of the lower semiconductor chip corresponding region.

In the intermediate ball land of the lower substrate, a dummy ball land in which dummy solder balls may be attached in at least one direction with respect to the lower substrate may be formed.

According to an exemplary embodiment of the inventive concept, a semiconductor stack package apparatus includes an upper semiconductor package including at least four upper semiconductor chips that have chip pads formed on their active surfaces in front, rear, left, and right directions, an upper substrate that supports the upper semiconductor chip, that has a substrate pad formed on its top surface in a corresponding direction to the chip pad, and that has an intermediate solder ball attached on an upper ball land formed on its bottom surface, a wire that electrically connects the chip pad and the substrate pad, and an encapsulation member that protects the active surface of the upper semiconductor chip and the wire by surrounding the active surface and the wire. The semiconductor stack package apparatus further includes a lower semiconductor package including a lower semiconductor chip that has a bump formed on its active surface, and a lower substrate that supports the lower semiconductor chip, that has a bump land corresponding to the bump, and an intermediate ball land corresponding to the intermediate solder ball formed on its top surface, and that has a lower solder ball attached to a lower ball land formed on its bottom surface. The bump land of the lower substrate corresponds to the bump of the lower semiconductor chip, and includes a first interface unit that is electrically connected to a first semiconductor chip of the upper semiconductor chip and that is disposed on a first end of a lower semiconductor chip corresponding region. The bump land further includes a fourth interface unit that is electrically connected to a fourth semiconductor chip of the upper semiconductor chip and that is disposed together with the first interface unit on the first end of the lower semiconductor chip corresponding region. The bump land further includes a second interface unit that is electrically connected to a second semiconductor chip of the upper semiconductor chip and that is disposed on a second end of the lower semiconductor chip corresponding region. The bump land further includes a third interface unit that is electrically connected to a third semiconductor chip of the upper semiconductor chip and that is disposed together with the second interface unit on the second end of the lower semiconductor chip corresponding region.

According to an exemplary embodiment of the inventive concept, a semiconductor package includes a substrate including a plurality of substrate pads, a first semiconductor chip disposed on the substrate and including a plurality of chip pads disposed on one end of the first semiconductor chip, a second semiconductor chip disposed on the first semiconductor chip and including a plurality of chip pads disposed on one end of the second semiconductor chip, a third semiconductor chip disposed on the substrate and including a plurality of chip pads disposed on one end of the third semiconductor chip, a fourth semiconductor chip disposed on the third semiconductor chip and including a plurality of chip pads disposed on one end of the fourth semiconductor chip, and a plurality of wires electrically connecting the chip pads of the first through fourth semiconductor chips to the plurality of substrate pads.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a cross-sectional view of a semiconductor stack package apparatus, according to an exemplary embodiment of the inventive concept;

FIG. 2 is a perspective view illustrating a state in which an encapsulation member is removed from the semiconductor stack package apparatus of FIG. 1;

FIG. 3 is an exploded perspective view illustrating the semiconductor stack package apparatus of FIG. 1, according to an exemplary embodiment of the inventive concept;

FIG. 4 is a plan view illustrating the semiconductor stack package apparatus of FIG. 2, according to an exemplary embodiment of the inventive concept;

FIG. 5 is a perspective view of an upper semiconductor chip of FIG. 1, according to an exemplary embodiment of the inventive concept;

FIGS. 6 and 7 are plan views illustrating an upper semiconductor chip of a semiconductor stack package apparatus, according to exemplary embodiments of the inventive concept;

FIG. 8 is a perspective view of an upper semiconductor chip of a semiconductor stack package apparatus, according to an exemplary embodiment of the inventive concept;

FIGS. 9 through 12 are plan views illustrating upper semiconductor chips of semiconductor stack package apparatuses, according to exemplary embodiments of the inventive concept;

FIG. 13 is a cross-sectional view of a semiconductor stack package apparatus, according to an exemplary embodiment of the inventive concept;

FIG. 14 is a cross-sectional view of the semiconductor stack package apparatus of FIG. 13, taken along line X IV-X IV, according to an exemplary embodiment of the inventive concept;

FIG. 15 is a plan view of the semiconductor stack package apparatus of FIG. 13, according to an exemplary embodiment of the inventive concept;

FIG. 16 is a cross-sectional view of a semiconductor stack package apparatus, according to an exemplary embodiment of the inventive concept;

FIG. 17 is a cross-sectional view of the semiconductor stack package apparatus of FIG. 16, taken along line X VII-X VII, according to an exemplary embodiment of the inventive concept;

FIG. 18 is a cross-sectional view of a semiconductor stack package apparatus, according to an exemplary embodiment of the inventive concept;

FIG. 19 is a cross-sectional view of the semiconductor stack package apparatus of FIG. 18, taken along line X IX-X IX, according to an exemplary embodiment of the inventive concept;

FIG. 20 is a cross-sectional view of a semiconductor stack package apparatus, according to an exemplary embodiment of the inventive concept;

FIG. 21 is a plan view illustrating a lower substrate of the semiconductor stack package apparatus of FIG. 1, according to an exemplary embodiment of the inventive concept;

FIGS. 22 through 24 are plan views illustrating lower substrates of semiconductor stack package apparatuses, according to exemplary embodiments of the inventive concept;

FIG. 25 is a cross-sectional view illustrating a semiconductor stack package apparatus mounted on a board substrate, according to an exemplary embodiment of the inventive concept;

FIG. 26 is a block diagram illustrating a memory card including a semiconductor stack package apparatus, according to an exemplary embodiment of the inventive concept; and

FIG. 27 is a block diagram illustrating an electronic system including a semiconductor stack package apparatus, according to an exemplary embodiment of the inventive concept.

### DETAILED DESCRIPTION OF THE EXEMPLARY EMBODIMENTS

Exemplary embodiments of the inventive concept will be described more fully hereinafter with reference to the accompanying drawings. Like reference numerals may refer to like elements throughout the accompanying drawings.

Throughout the specification, it will be understood that when an element such as a layer, region, or substrate is referred to as being “on”, “connected to” or “coupled with” another element, it can be directly on the other element, or intervening elements may also be present.

The terms “first” and “second” are used to distinguish between each of components, parts, regions, layers and/or portions. Thus, throughout the specification, a first component, a first part, a first region, a first layer or a first portion may indicate a second component, a second part, a second region, a second layer or a second portion.

In addition, relative terms such as “lower” or “bottom”, and “upper” or “top” may be used to describe the relationship between elements as illustrated in the drawings. These relative terms can be understood to include different directions in addition to the described directions illustrated in the drawings.

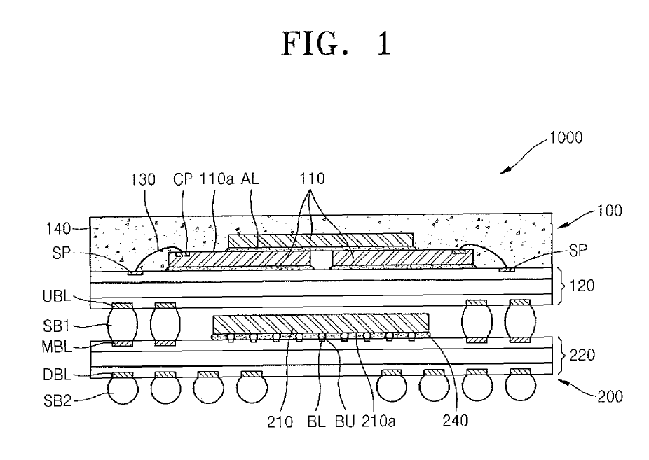

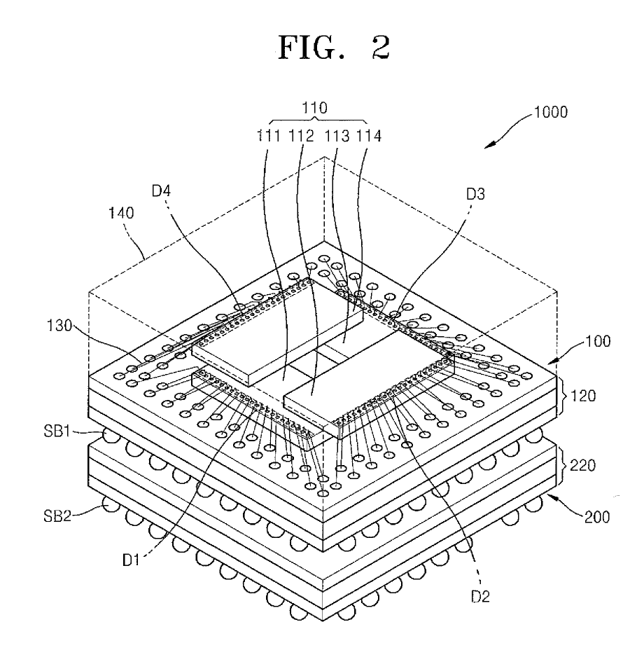

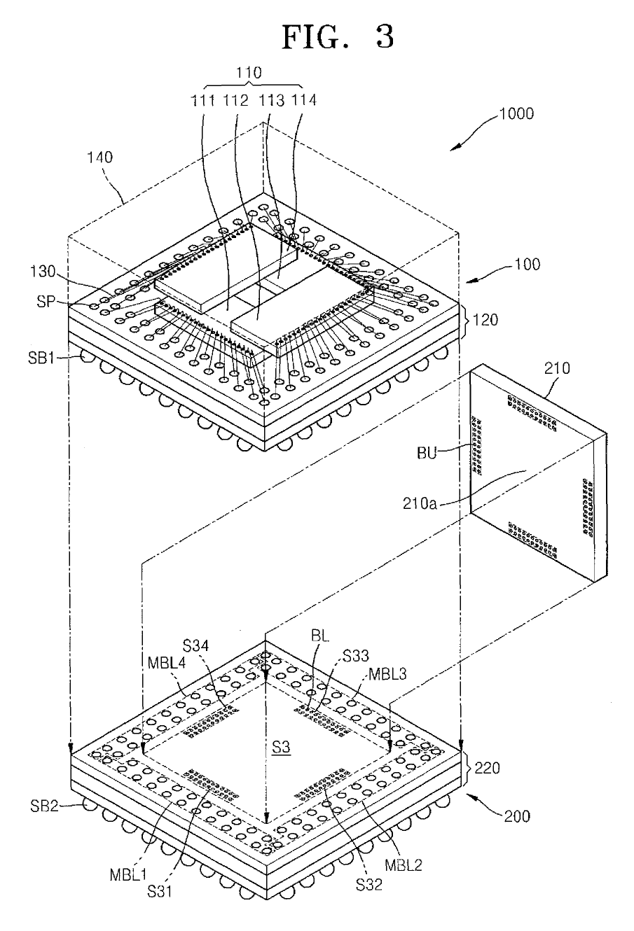

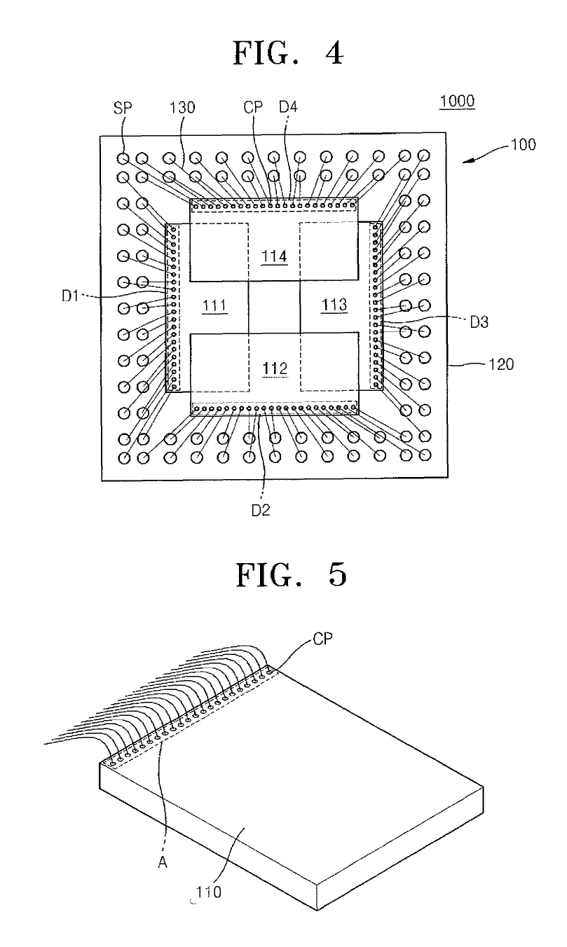

FIG. 1 is a cross-sectional view of a semiconductor stack package apparatus 1000, according to an exemplary embodiment of the inventive concept. FIG. 2 is a perspective view illustrating a state in which an encapsulation member 140 is removed from the semiconductor stack package apparatus 1000, according to an exemplary embodiment. FIG. 3 is an exploded perspective view illustrating the semiconductor stack package apparatus 1000 of FIG. 1, according to an exemplary embodiment. FIG. 4 is a plan view illustrating the semiconductor stack package apparatus 1000 shown in FIG. 2, according to an exemplary embodiment. FIG. 5 is a perspective view of an upper semiconductor chip 110 of FIG. 1, according to an exemplary embodiment.

As illustrated in FIGS. 1 through 5, the semiconductor stack package apparatus 1000 may include an upper semiconductor package 100 and a lower semiconductor package 200. The semiconductor stack package apparatus 1000 may be, for example, a package-on-package (POP) type semiconductor stack package apparatus formed by stacking the upper semiconductor package 100 on the lower semiconductor package 200.

In FIG. 1, the upper semiconductor package 100 includes an upper semiconductor chip 110, an upper substrate 120, a wire 130, and the encapsulation member 140. The upper semiconductor chip 110 may have a chip pad CP formed on its active surface 110a, and the upper semiconductor package 100 may include one or more upper semiconductor chips 110. In an exemplary embodiment, the semiconductor stack package apparatus 1000 is a system-in-package type semiconductor stack package apparatus having semiconductor chips (e.g., a memory chip and a control chip) that perform a plurality of functions integrated into one package, and the upper semiconductor chip 110 may be formed of four stacked memory chips. For example, the lower semiconductor package 200 may include a control chip having four control channels, and the four stacked memory chips may be selectively controlled. The number of upper semiconductor chips 110 is not limited to four chips, and may be greater or less than four chips.

The upper substrate 120 supports the upper semiconductor chip 110, has a substrate pad SP formed on its top surface, and has an intermediate solder ball SB1 attached on an upper ball land UBL that is formed on its bottom surface. The upper substrate 120 may be formed such that a wiring layer is formed on a top surface and a bottom surface of an insulating substrate member. The wiring layer may be formed, for example, using an adhering, plating, or thermal-pressing process. However, the material and methods used for forming the upper substrate 120 are not limited thereto.

The wire 130 serves as a signal delivering medium for electrically connecting the chip pad CP and the substrate pad SP. In exemplary embodiments, a bump or a solder ball may be used as the signal delivering medium. The wire 130 may be used for bonding a semiconductor, and may be formed of, for example, gold (Au), silver (Ag), platinum (Pt), aluminum (Al), copper (Cu), palladium (Pd), nickel (Ni), cobalt (Co), chrome (Cr), or titanium (Ti), and may be formed by using a wire bonding apparatus. However, the material and method used for forming the wire 130 is not limited thereto.

The encapsulation member 140 may surround and protect the active surface 110a of the upper semiconductor chip 110 and the wire, and may be formed of synthetic resin-based materials including, for example, epoxy resin, a curing agent, and organic or inorganic filling materials. The encapsulation member 140 may then be injection-molded in a mold. The encapsulation member 140 may be formed of, for example, a polymer such as resin or an epoxy molding compound (EMC). However, the material and method used for forming the encapsulation member 140 is not limited thereto.

In FIG. 1, the lower semiconductor package 200 includes a lower semiconductor chip 210, a lower substrate 220, and an underfill member 240.

The lower semiconductor chip 210 has a bump BU formed on its active surface 210a. In an exemplary embodiment, the semiconductor stack package apparatus 1000 is a system-in-package type semiconductor stack package apparatus in which semiconductor chips (e.g., a memory chip and a control chip) that perform a plurality of functions are integrated into one package, and the lower semiconductor chip 210 is a control chip having four control channels that selectively control four memory chips stacked in the upper semiconductor package 100. As illustrated in FIG. 1, the lower semiconductor chip 210 may be a flip-chip having an active surface 210a that faces downward. However, the lower semiconductor chip 210 is not limited thereto.

The bump BU may be formed of, for example, gold (Au), silver (Ag), platinum (Pt), aluminum (Al), copper (Cu), or solder, and may be manufactured using, for example, various depositing processes, a sputtering process, a plating process including pulse-plating or direct current plating, a soldering process, or an adhering process. However, the material and manufacturing method of the bump BU is not limited thereto. In an exemplary embodiment, a wire or a solder ball other than the bump BU may be used as the signal delivering medium.

In FIG. 1, the lower substrate 220 supports the lower semiconductor chip 210, and has a bump land BL corresponding to the bump BU, an intermediate ball land MBL corresponding to the intermediate solder ball SB1 formed on its top surface, and a lower solder ball SB2 attached to a lower ball land DBL that is formed on its bottom surface. The lower substrate 220 may be formed such that a wiring layer is formed on a top surface and a bottom surface of an insulating substrate member by adhering, plating, or thermal-pressing. However, the material and method used for forming the lower substrate 220 is not limited thereto.

The underfill member 240 may surround and protect the active surface 210a of the lower semiconductor chip 210 and the bump BU. The underfill member 240 may further fill a gap between the lower substrate 220 and the active surface 210a of the lower semiconductor chip 210, or a gap between the upper semiconductor package 100 and the lower semiconductor package 200. The underfill member 240 may be formed of an underfill resin such as, for example, an epoxy resin, or may include a silica filler for flux. The underfill member 240 may be formed of a different material from the encapsulation member 140, or may be formed of the same material as the encapsulation member 140. In exemplary embodiments, the underfill member 240 may be omitted, or may be replaced by an adhesive tape or an encapsulating tape.

As illustrated in FIG. 5, all chip pads CP on the upper semiconductor chip 110 are integrated and formed on one end A. The chip pads CP may include both DQchip pads that input and output signals related to data, and CA chip pads that input and output signals related to addresses and power.

As illustrated in FIGS. 1 through 4, the upper semiconductor chip 110 may include four semiconductor chips, including a first semiconductor chip 111 in which all chip pads CP are integrated and formed on a first end D1 extending in a first direction, a second semiconductor chip 112 in which all chip pads CP are integrated and formed on a second end D2 extending in a second direction, a third semiconductor chip 113 in which all chip pads CP are integrated and formed on a third end D3 extending in a third direction, and a fourth semiconductor chip 114 in which all chip pads CP are integrated and formed on a fourth end D4 extending in a fourth direction. As illustrated in FIGS. 1 through 4, the first end D1 may correspond to a front area, the second end D2 may correspond to a left area, the third end D3 may correspond to a rear area, and the fourth end D4 may correspond to a right area, however, exemplary embodiments of the inventive concept are not limited thereto.

As illustrated in FIGS. 1 through 4, the first semiconductor chip 111 and the third semiconductor chip 113 are mounted in parallel, and form a first layer on the top surface of the upper substrate 120. The second semiconductor chip 112 and the fourth semiconductor chip 114 are stacked in parallel, and form a second layer on top surfaces of the first semiconductor chip 111 and the third semiconductor chip 113. An adhesive layer AL may be formed on bottom surfaces of the first semiconductor chip 111 and the third semiconductor chip 113, the top surface of the upper substrate 120, bottom surfaces of the second semiconductor chip 112 and the fourth semiconductor chip 114, and the top surfaces of the first semiconductor chip 111 and the third semiconductor chip 113. The adhesive layer AL may be formed of, for example, an insulating adhesive resin material or a soft adhesive tape.

In the semiconductor stack package apparatus 1000 according to the exemplary embodiment described above, the four upper semiconductor chips 111, 112, 113 and 114 of the upper semiconductor chip 110 are stacked and form two layers. As a result, the thickness of the upper semiconductor chip 110 may be reduced. Further, due to the location of the first, second, third and fourth ends D1, D2, D3 and D4, wiring paths may be uniformly laid out (e.g., the wiring paths may not be substantially longer or shorter in different directions). Decreasing a difference between lengths of the wiring paths may improve the reliability and function of the upper semiconductor chip 110 as an operation frequency of the chip 110 increases. As illustrated in FIG. 5, in the semiconductor stack package apparatus 1000, all chip pads CP of the first, second, third and fourth semiconductor chips 111, 112, 113, and 114 are integrated on each side end A. As illustrated in FIGS. 1 through 4, since the first, second, third and fourth ends D1, D2, D3 and D4 are disposed in the front, left, rear and right areas, respectively, a difference between the wiring paths between the first, second, third and fourth semiconductor chips 111, 112, 113 and 114 may be reduced. In an exemplary embodiment where the upper semiconductor chip 110 is formed of four memory chips and the lower semiconductor chip 210 is formed of a control chip having four control channels that control the four memory chips, respectively, the control chip may operate the four memory chips without temporal deviation.

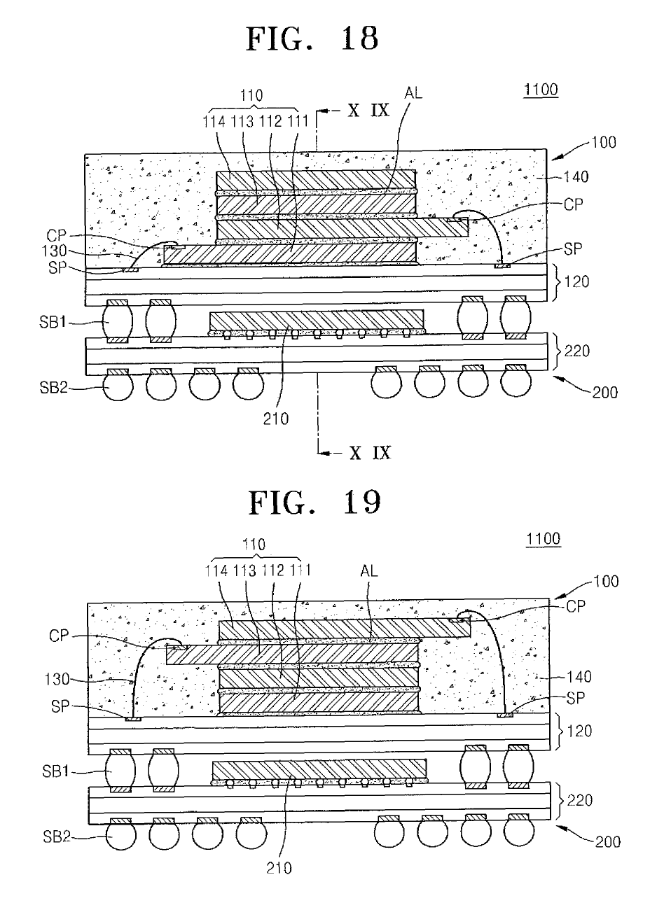

FIGS. 18 and 19 illustrate a semiconductor stack package apparatus 1100, according to exemplary embodiments of the inventive concept.

As illustrated in FIGS. 18 and 19, in a semiconductor stack package apparatus 1100, the first, second, third and fourth semiconductor chips 111, 112, 113 and 114 may be formed on separate layers, resulting in the formation of four layers. For example, the first semiconductor chip 111 may be mounted on the top surface of the upper substrate 120, the second semiconductor chip 112 may be mounted on a top surface of the first semiconductor chip 111, the third semiconductor chip 113 may be mounted on a top surface of the second semiconductor chip 112, and the fourth semiconductor chip 114 may be mounted on a top surface of the third semiconductor chip 113.

An adhesive layer AL is formed on each bottom surface of the first, second, third and fourth semiconductor chips 111, 112, 113 and 114, bonding the four chips. The adhesive layer AL may be formed of, for example, an insulating adhesive resin material or a soft adhesive tape.

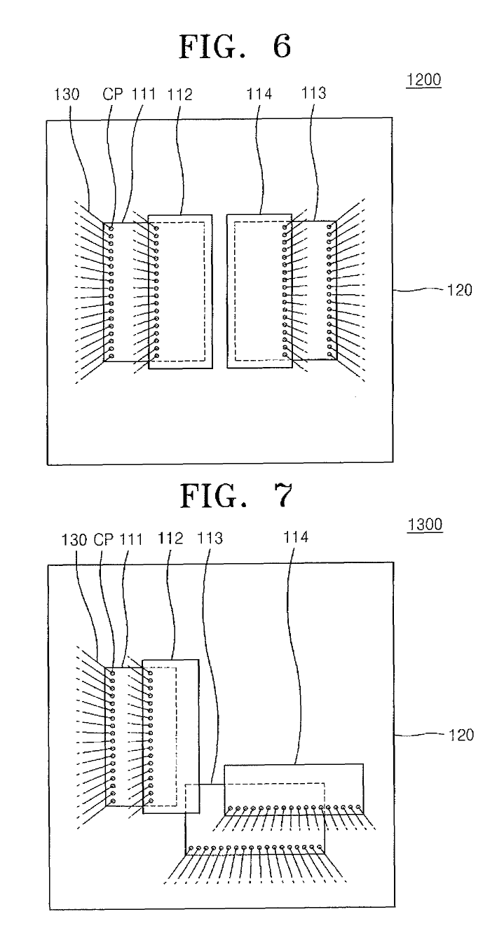

FIGS. 6 and 7 are plan views illustrating the upper semiconductor chip 110 of the semiconductor stack package apparatuses 1200 and 1300, according to exemplary embodiments of the inventive concept.

As illustrated in FIG. 6, in the semiconductor stack package apparatus 1200 according to an exemplary embodiment, the second semiconductor chip 112 is stacked on the first semiconductor chip 111, and the first direction and the second direction are substantially the same. The fourth semiconductor chip 114 is stacked on the third semiconductor chip 113, and the third direction and the fourth direction are substantially the same. The first, second, third and fourth directions are substantially parallel with each other. For convenience of description, the plurality of substrate pads SP shown in FIG. 4 are omitted in FIG. 6. The substrate pads SP may be uniformly disposed on four ends or two ends of the upper substrate 120, and the wires 130 may electrically connect the substrate pads SP and the chip pads CP, respectively.

As illustrated in FIG. 7, in the semiconductor stack package apparatus 1300 according to an exemplary embodiment, the second semiconductor chip 112 is stacked on the first semiconductor chip 111, and the first direction and the second direction are substantially the same. The fourth semiconductor chip 114 is stacked on the third semiconductor chip 113, and the third direction and the fourth direction are substantially the same. The first and second directions are substantially perpendicular to the third and fourth directions. For convenience of description, the plurality of substrate pads SP shown in FIG. 4 are omitted in FIG. 6. The substrate pads SP may be uniformly disposed on four ends or two ends of the upper substrate 120, and the wires 130 may electrically connect the substrate pads SP and the chip pads CP, respectively.

FIG. 8 is a perspective view of an upper semiconductor chip 150 of a semiconductor stack package apparatus 1400, according to an exemplary embodiment of the inventive concept.

As illustrated in FIG. 8, the upper semiconductor chip 150 includes chip pads CP integrated and formed on ends A and C. On the upper semiconductor chip 150, DQ chip pads, which are used to input and output signals related to data, are integrated on end A, and CA chip pads, which are used to input and output signals related to addresses and power, are integrated on end C.

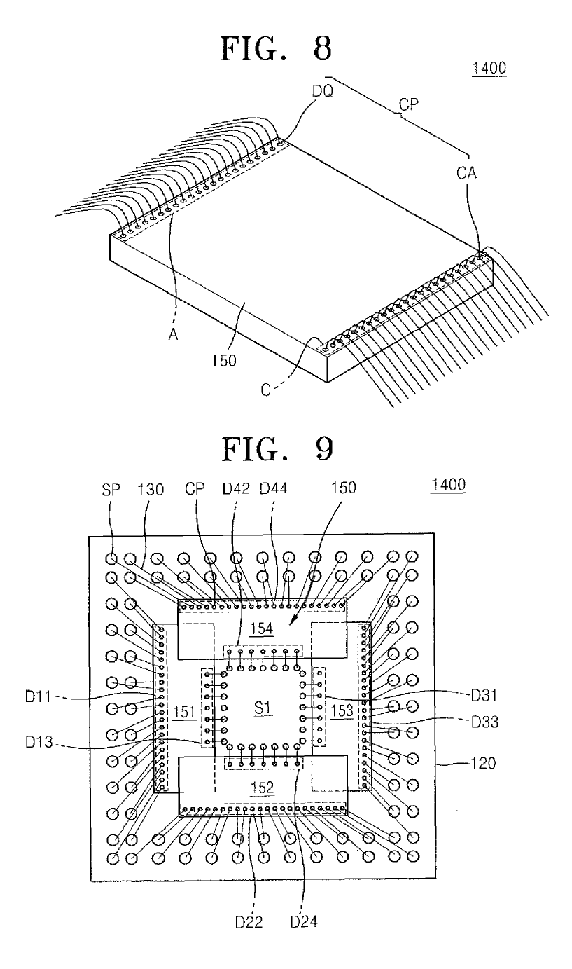

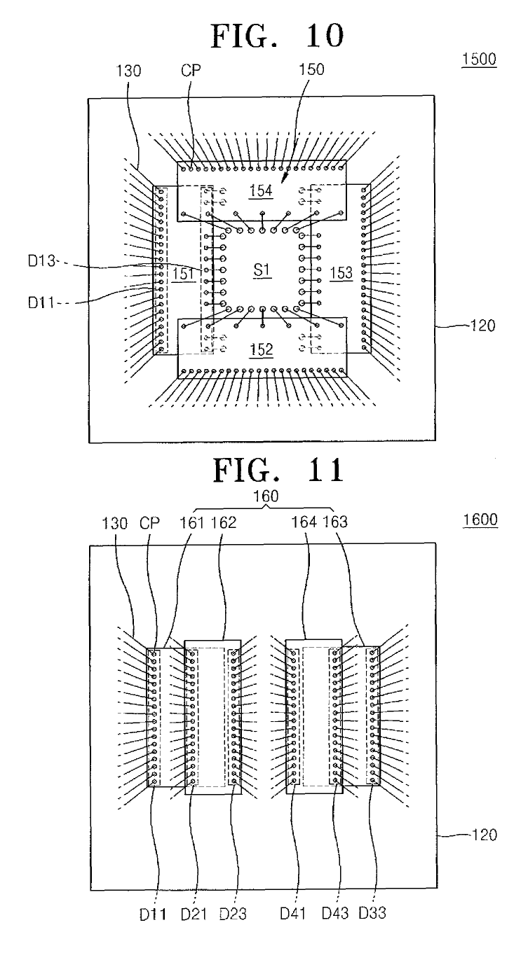

FIGS. 9 and 10 are plan views illustrating first, second, third and fourth semiconductor chips 151, 152, 153 and 154, of each semiconductor stack package apparatus 1400 and 1500, according to exemplary embodiments of the inventive concept.

As illustrated in FIG. 9, an upper semiconductor chip 150 of the semiconductor stack package apparatus 1400 includes the first semiconductor chip 151, the second semiconductor chip 152, the third semiconductor chip 153 and the fourth semiconductor chip 154.

The first semiconductor chip 151 may include CP chip pads integrated and formed on a first end D11 extending in a first direction, and a third end D13 extending in a third direction. The second semiconductor chip 152 may include CP chip pads integrated and formed on a second end D22 extending in a second direction, and a fourth end D24 extending in a fourth direction. The third semiconductor chip 153 may include CP chip pads integrated and formed on a third end D33 extending in a third direction, and a first end D31 extending in a first direction. The fourth semiconductor chip 154 may include CP chip pads integrated and formed on a fourth end D44 extending in a fourth direction, and a second end D42 extending in a second direction.

In FIG. 9, the first semiconductor chip 151 and the third semiconductor chip 153 are mounted on a top surface of an upper substrate 120, the second semiconductor chip 152 and the fourth semiconductor chip 154 are mounted on top surfaces of the first semiconductor chip 151 and the third semiconductor chip 153, and an inner wire bonding space S1 is formed between the first semiconductor chip 151 and the third semiconductor chip 153, and between the second semiconductor chip 152 and the fourth semiconductor chip 154.

That is, substrate pads SP may be formed on four ends of the upper substrate 120, as well as in the inner wire bonding space S1, and wires 130 may electrically connect the substrate pads SP formed in the inner wire bonding space S1 and the chip pads CP.

As illustrated in FIG. 10, in the semiconductor stack package apparatus 1500, a portion of a third end D13 of the first semiconductor chip 151 may be disposed below the fourth semiconductor chip 154 and the second semiconductor chip 152. That is, in an exemplary embodiment, the first semiconductor chip 151 may first be mounted on the upper substrate 120, and then the third end D13 may be wired. Afterward, an adhesive layer AL formed of, for example, a soft adhesive tape, may cover the first semiconductor chip 151, and the fourth semiconductor chip 154 and the second semiconductor chip 152 may then be stacked thereon.

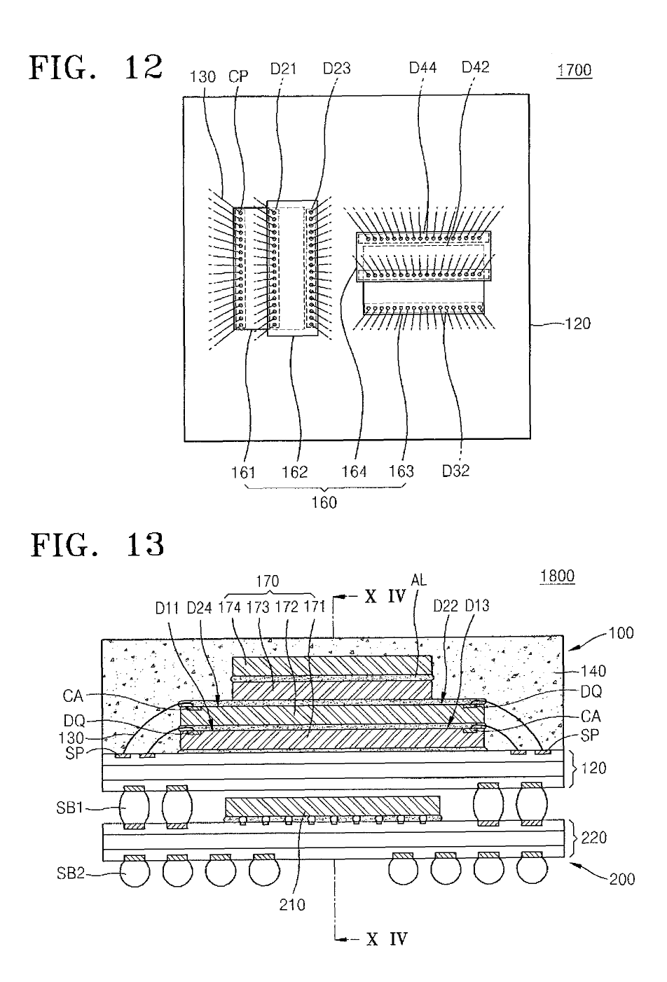

FIGS. 11 and 12 are plan views illustrating first, second, third and fourth semiconductor chips 161, 162, 163 and 164, of each semiconductor stack package apparatus 1600 and 1700, according to exemplary embodiments of the inventive concept.

As illustrated in FIG. 11, in an exemplary embodiment, an upper semiconductor chip 160 of the semiconductor stack package apparatus 1600 includes the first semiconductor chip 161, the second semiconductor chip 162, the third semiconductor chip 163 and the fourth semiconductor chip 164. The first semiconductor chip 161 includes chip pads CP integrated and formed on a first end D11 extending in a first direction. The second semiconductor chip 162 includes chip pads CP integrated and formed on a second end D21 extending in a second direction, and a fourth end D23 extending in a fourth direction. The third semiconductor chip 163 includes chip pads CP integrated and formed on a third end D33 extending in a third direction. The fourth semiconductor chip 164 includes chip pads CP integrated and formed on a fourth end D41 extending in a fourth direction, and a second end D43 extending in a second direction. The second semiconductor chip 162 may be stacked on the first semiconductor chip 161, and the first direction and the second direction may be substantially the same. The fourth semiconductor chip 164 may be stacked on the third semiconductor chip 163, and the third direction and the fourth direction may be substantially the same, and may be substantially parallel with the first and second directions. For convenience of description, the plurality of substrate pads SP shown in FIG. 4 are omitted in FIG. 11. The substrate pads SP may be uniformly disposed on four ends or two ends of an upper substrate 120, and the wires 130 may electrically connect the substrate pads SP and the chip pads CP, respectively.

As illustrated in FIG. 12, in an exemplary embodiment, an upper semiconductor chip 160 of the semiconductor stack package apparatus 1700 includes the first semiconductor chip 161, the second semiconductor chip 162, the third semiconductor chip 163 and the fourth semiconductor chip 164. The first semiconductor chip 161 includes chip pads CP integrated and formed on a first end D11 extending in a first direction. The second semiconductor chip 162 includes chip pads CP integrated and formed on a second end D21 extending in a second direction, and a fourth end D23 extending in a fourth direction. The third semiconductor chip 163 includes chip pads CP integrated and formed on a third end D32 extending in a third direction. The fourth semiconductor chip 164 includes chip pads CP integrated and formed on a fourth end D44 extending in a fourth direction, and a second end D42 extending in a second direction. The second semiconductor chip 162 may be stacked on the first semiconductor chip 161, and the first direction and the second direction may be substantially the same. The fourth semiconductor chip 164 may be stacked on the third semiconductor chip 163, and the third direction and the fourth direction may be substantially the same, and may be substantially perpendicular to the first and second directions. For convenience of description, the plurality of substrate pads SP shown in FIG. 4 are omitted in FIG. 12. The substrate pads SP may be uniformly disposed on four ends or two ends of an upper substrate 120, and the wires 130 may electrically connect the substrate pads SP and the chip pads CP, respectively.

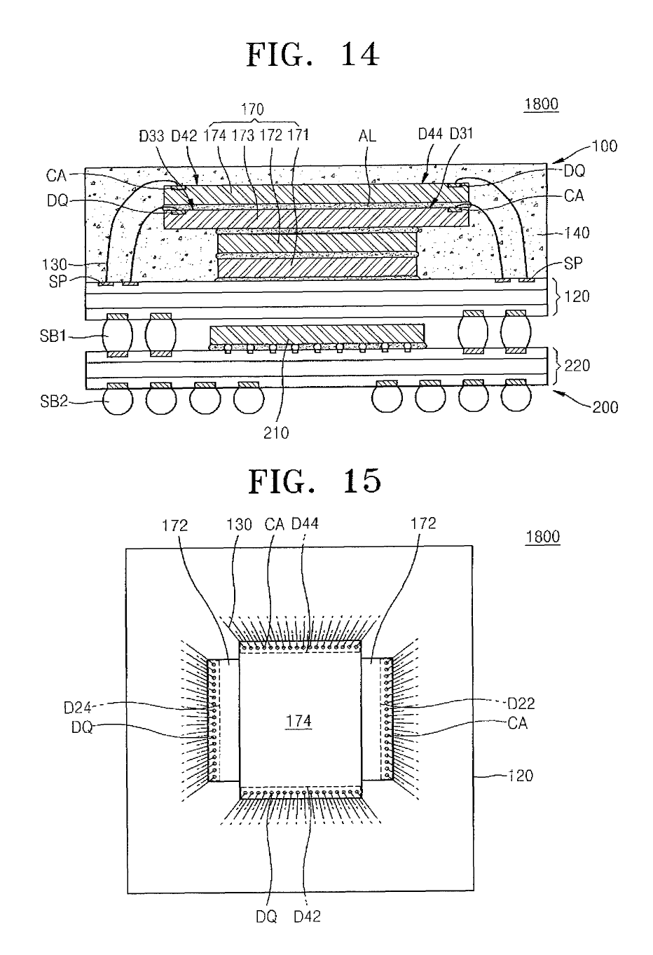

FIG. 13 is a cross-sectional view of a semiconductor stack package apparatus 1800, according to an exemplary embodiment of the inventive concept. FIG. 14 is a cross-sectional view of the semiconductor stack package apparatus 1800 of FIG. 13, taken along line X IV-X IV. FIG. 15 is a plan view of the semiconductor stack package apparatus 1800 of FIG. 13.

As illustrated in FIGS. 13 through 15, an upper semiconductor chip 170 of the semiconductor stack package apparatus 1800 may include a semiconductor chip including DQ chip pads integrated on one end A and CA chip pads integrated on another end C.

Referring to FIGS. 13 through 15, in an exemplary embodiment, the upper semiconductor chip 170 includes a first semiconductor chip 171, a second semiconductor chip 172, a third semiconductor chip 173 and a fourth semiconductor chip 174. The first semiconductor chip 171 includes DQ chip pads integrated on a first end D11, and CA chip pads integrated on a third end D13. The second semiconductor chip 172 includes DQ chip pads integrated on a second end D22, and CA chip pads integrated on a fourth end D24. The third semiconductor chip 173 includes DQ chip pads integrated on a third end D33, and CA chip pads integrated on a first end D31. The fourth semiconductor chip 174 includes DQ chip pads integrated on a fourth end D44, and CA chip pads integrated on a second end D42.

The first semiconductor chip 171 may be mounted on a top surface of the upper substrate 120, the second semiconductor chip 172 may be stacked on a top surface of the first semiconductor chip 171, the third semiconductor chip 173 may be stacked on a top surface of the second semiconductor chip 172, and the fourth semiconductor chip 174 may be stacked on a top surface of the third semiconductor chip 173. The first semiconductor chip 171 and the second semiconductor chip 172 may be stacked such that they are substantially aligned with each other, the second semiconductor chip 172 and the third semiconductor chip 173 may be stacked such that they are substantially transverse to each other, and the third semiconductor chip 173 and the fourth semiconductor chip 174 may be stacked such that they are substantially aligned with each other. Thus, as illustrated in FIG. 15, the DQ chip pads and the CA chip pads are uniformly disposed in front, rear, left and right areas with respect to the upper substrate 120. As a result, a difference between wiring paths between the first, second, third and fourth semiconductor chips 171, 172, 173, and 174 may be reduced.

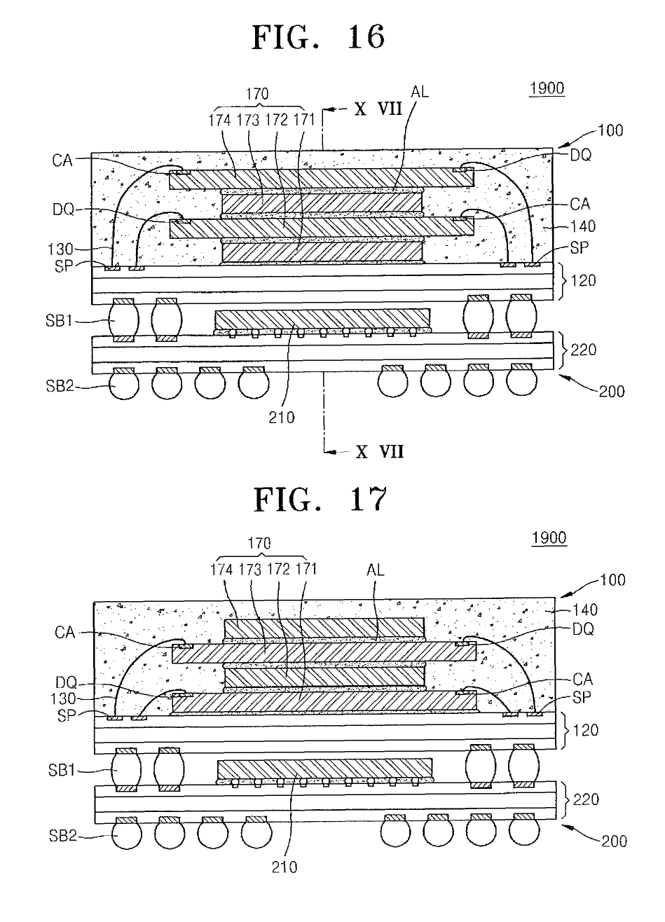

FIG. 16 is a cross-sectional view of a semiconductor stack package apparatus 1900, according to an exemplary embodiment of the inventive concept. FIG. 17 is a cross-sectional view of the semiconductor stack package apparatus 1900 of FIG. 16, taken along line X VII-X VII.

As illustrated in FIGS. 16 and 17, the upper semiconductor chip 170 of the semiconductor stack package apparatus 1900 includes a semiconductor chip in which DQ chip pads are integrated on one side, and CA chip pads are integrated on another side. The first semiconductor chip 171 may be mounted on the top surface of the upper substrate 120, the second semiconductor chip 172 may be stacked on a top surface of the first semiconductor chip 171, the third semiconductor chip 173 may be stacked on a top surface of the second semiconductor chip 172, and the fourth semiconductor chip 174 may be stacked on a top surface of the third semiconductor chip 173. The first semiconductor chip 171 and the second semiconductor chip 172 may be substantially transverse to each other, the second semiconductor chip 172 and the third semiconductor chip 173 may be substantially transverse to each other, and the third semiconductor chip 173 and the fourth semiconductor chip 174 may be substantially transverse to each other. Thus, as illustrated in FIGS. 16 and 17, the DQ chip pads and the CA chip pads are uniformly disposed in front, rear, left and right areas with respect to the upper substrate 120. As a result, a difference between wiring paths between the first, second, third and fourth semiconductor chips 171, 172, 173 and 174 may be reduced.

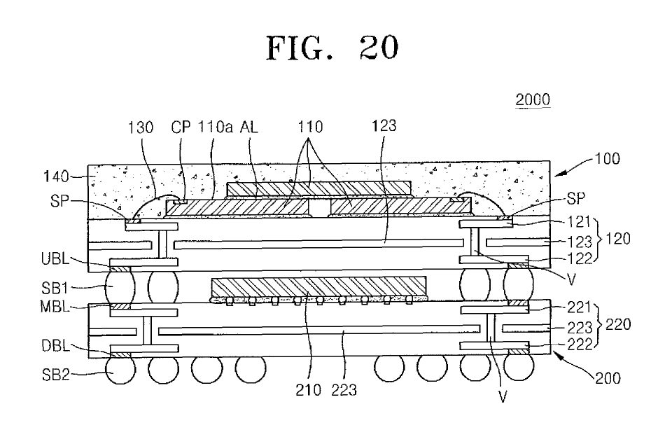

FIG. 20 is a cross-sectional view of a semiconductor stack package apparatus 2000, according to an exemplary embodiment of the inventive concept.

As illustrated in FIG. 20, the upper substrate 120 includes a first redistribution layer 121, a second redistribution layer 122, and a metal core layer 123. The first redistribution layer 121 is electrically connected to the substrate pad SP. The first redistribution layer 121 may be disposed on an insulating layer that surrounds the metal core layer 123, and may be formed by performing an adhering process, a pressing process, or a metalizing process. The insulating layer may surround and protect the metal core layer 123, the first redistribution layer 121, and the second redistribution layer 122, and may be, for example, solder-resist. The second redistribution layer 122 is electrically connected to the first redistribution layer 121 by a via electrode V that penetrates through the insulating layer and is electrically connected to the upper ball land UBL. The second redistribution layer 122 may be disposed below the insulating layer that surrounds the metal core layer 123, and may be formed by performing an adhering process, a pressing process, or a metalizing process. The metal core layer 123 may be formed between the first redistribution layer 121 and the second redistribution layer 122 so as to prevent electrical interference between the first redistribution layer 121 and the second redistribution layer 122. The metal core layer 123 may also reduce electrical interference between the first redistribution layer 121 and the second redistribution layer 122 by absorbing electromagnetic waves that occur in each of the first redistribution layer 121 and the second redistribution layer 122. The metal core layer 123 may be connected to a ground voltage source. The metal core layer 123 may be formed of, for example, gold (Au), silver (Ag), platinum (Pt), aluminum (Al), copper (Cu), palladium (Pd), nickel (Ni), cobalt (Co), chrome (Cr) or titanium (Ti), and may be formed by performing an adhering process, a pressing process, or a metalizing process in a substrate core process. However, a material or a forming method of the metal core layer 123 is not limited thereto.

Further, as illustrated in FIG. 20, the lower substrate 220 includes a first redistribution layer 221, a second redistribution layer 222 and a metal core layer 223. The first redistribution layer 221 is electrically connected to the intermediate ball land MBL. The first redistribution layer 221 may be disposed on an insulating layer that surrounds the metal core layer 223, and may be formed by performing an adhering process, a pressing process, or a metalizing process. The insulating layer may surround and protect the metal core layer 223, the first redistribution layer 221, and the second redistribution layer 222, and may be, for example, solder-resist. The second redistribution layer 222 is electrically connected to the first redistribution layer 221 by a via electrode V, which is electrically connected to the lower ball land DBL. The second redistribution layer 222 may be disposed below the insulating layer that surrounds the metal core layer 223, and may be formed by performing an adhering process, a pressing process, or a metalizing process. The metal core layer 223 may be formed between the first redistribution layer 221 and the second redistribution layer 222, and may prevent or reduce electrical interference between the first redistribution layer 221 and the second redistribution layer 222. The metal core layer 223 may also reduce the electrical interference between the first redistribution layer 221 and the second redistribution layer 222 by absorbing electromagnetic waves that occur in each of the first redistribution layer 221 and the second redistribution layer 222. The metal core layer 223 may be connected to a ground voltage source. The metal core layer 223 may be formed of, for example, gold (Au), silver (Ag), platinum (Pt), aluminum (Al), copper (Cu), palladium (Pd), nickel (Ni), cobalt (Co), chrome (Cr) or titanium (Ti), and may be formed by performing an adhering process, a pressing process, or a metalizing process in a substrate core process. However, a material or a forming method of the metal core layer 223 is not limited thereto.

FIG. 21 is a plan view illustrating the lower substrate 220 of the semiconductor stack package apparatus 1000 of FIGS. 1 through 4, according to an exemplary embodiment of the inventive concept.

As illustrated in FIG. 21, in the semiconductor stack package apparatus 1000, the bump land BL of the lower substrate 220, which corresponds to the bump BU of the lower semiconductor chip 210, may include a first interface unit BL1, a second interface unit BL2, a third interface unit BL3, and a fourth interface unit BL4. The first interface unit BL1 is a physical terminal that is electrically connected to an intermediate ball land unit MBL1 corresponding to the first semiconductor chip 111 of the upper semiconductor chip 110, and which is disposed on a first end S31 of a lower semiconductor chip corresponding region S3. The second interface unit BL2 is a physical terminal that is electrically connected to an intermediate ball land unit MBL2 corresponding to the second semiconductor chip 112 of the upper semiconductor chip 110, and which is disposed on a second end S32 of the lower semiconductor chip corresponding region S3. The third interface unit BL3 is a physical terminal that is electrically connected to an intermediate ball land unit MBL3 corresponding to the third semiconductor chip 113 of the upper semiconductor chip 110, and which is disposed on a third end S33 of the lower semiconductor chip corresponding region S3. The fourth interface unit BL4 is a physical terminal that is electrically connected to an intermediate ball land unit MBL4 corresponding to the fourth semiconductor chip 114 of the upper semiconductor chip 110, and which is disposed on a fourth end S34 of the lower semiconductor chip corresponding region S3. The intermediate ball land units MBL1, MBL2, MBL3 and MBL4 may surround the lower semiconductor chip corresponding region S3 in a manner such that two rows of the intermediate ball lands MBL are formed in each of the intermediate ball land units MBL1, MBL2, MBL3 and MBL4.

The intermediate ball land units MBL1, MBL2, MBL3 and MBL4, and the first, second, third, and fourth interface units BL1, BL2, BL3 and BL4, may be electrically connected to each other and may be redistributed via the first redistribution layer 221 of FIG. 20.

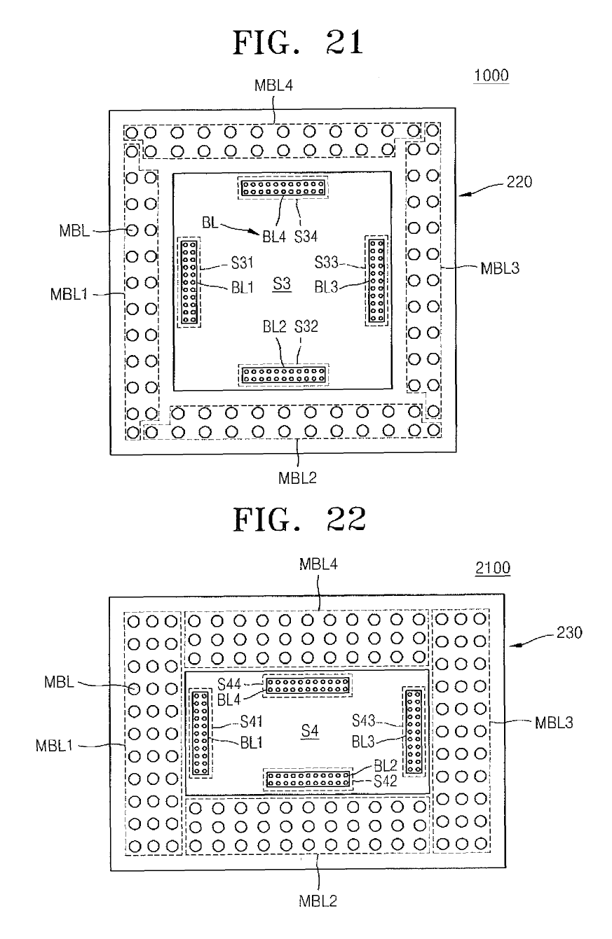

FIGS. 22 through 24 are plan views illustrating lower substrates 230, 240 and 250 of semiconductor stack package apparatuses 2100, 2200 and 2300, respectively, according to exemplary embodiments of the inventive concept.

As illustrated in FIG. 22, in the semiconductor stack package apparatus 2100, a bump land BL of the lower substrate 230, which corresponds to the bump BU of the lower semiconductor chip 210, may include a first interface unit BL1, a second interface unit BL2, a third interface unit BL3 and a fourth interface unit BL4. The first interface unit BL1 is a physical terminal that is electrically connected to an intermediate ball land unit MBL1 corresponding to the first semiconductor chip 111 of the upper semiconductor chip 110, and which is disposed on a first end S41 of a lower semiconductor chip corresponding region S4. The second interface unit BL2 is a physical terminal that is electrically connected to an intermediate ball land unit MBL2 corresponding to the second semiconductor chip 112 of the upper semiconductor chip 110, and which is disposed on a second end S42 of the lower semiconductor chip corresponding region S4. The third interface unit BL3 is a physical terminal that is electrically connected to an intermediate ball land unit MBL3 corresponding to the third semiconductor chip 113 of the upper semiconductor chip 110, and which is disposed on a third end S43 of the lower semiconductor chip corresponding region S4. The fourth interface unit BL4 is a physical terminal that is electrically connected to an intermediate ball land unit MBL4 corresponding to the fourth semiconductor chip 114 of the upper semiconductor chip 110, and which is disposed on a fourth end S44 of the lower semiconductor chip corresponding region S4.

The intermediate ball land units MBL1, MBL2, MBL3 and MBL4 may surround the lower semiconductor chip corresponding region S4 in a manner such that three rows of the intermediate ball lands MBL are formed in each of the intermediate ball land units MBL1, MBL2, MBL3 and MBL4, as shown in FIG. 22. However, the number, form and position of the intermediate ball lands MBL are not limited thereto. For example, in exemplary embodiments, one row, two rows, or four or more rows of the intermediate ball lands MBL may be formed.

The intermediate ball land units MBL1, MBL2, MBL3 and MBL4, and the first, second, third and fourth interface units BL1, BL2, BL3 and BL4 may be electrically connected to each other, and may be redistributed via the first redistribution layer 221 of FIG. 20.

As illustrated in FIG. 23, in the semiconductor stack package apparatus 2200 according to an exemplary embodiment, a bump land BL of the lower substrate 240, which corresponds to the bump BU of the lower semiconductor chip 210, may include a first interface unit BL1, a second interface unit BL2, a third interface unit BL3, and a fourth interface unit BL4. The first interface unit BL1 is a physical terminal that is electrically connected to an intermediate ball land unit MBL1 corresponding to the first semiconductor chip 111 of the upper semiconductor chip 110, and which is disposed on a first end S51 of a lower semiconductor chip corresponding region S5. The fourth interface unit BL4 is a physical terminal that is electrically connected to an intermediate ball land unit MBL4 corresponding to the fourth semiconductor chip 114 of the upper semiconductor chip 110, and which is disposed together with the first interface unit BL1 on the first end S51 of the lower semiconductor chip corresponding region S5. The second interface unit BL2 is a physical terminal that is electrically connected to an intermediate ball land unit MBL2 corresponding to the second semiconductor chip 112 of the upper semiconductor chip 110, and which is disposed on a second end S52 of the lower semiconductor chip corresponding region S5. The third interface unit BL3 is a physical terminal that is electrically connected to an intermediate ball land unit MBL3 corresponding to the third semiconductor chip 113 of the upper semiconductor chip 110, and which is disposed together with the second interface unit BL2 on the second end S52 of the lower semiconductor chip corresponding region S5.

The intermediate ball land units MBL1, MBL2, MBL3 and MBL4, and the first, second, third and fourth interface units BL1, BL2, BL3 and BL4 may be electrically connected to each other and may be redistributed via the first redistribution layer 221 of FIG. 20.

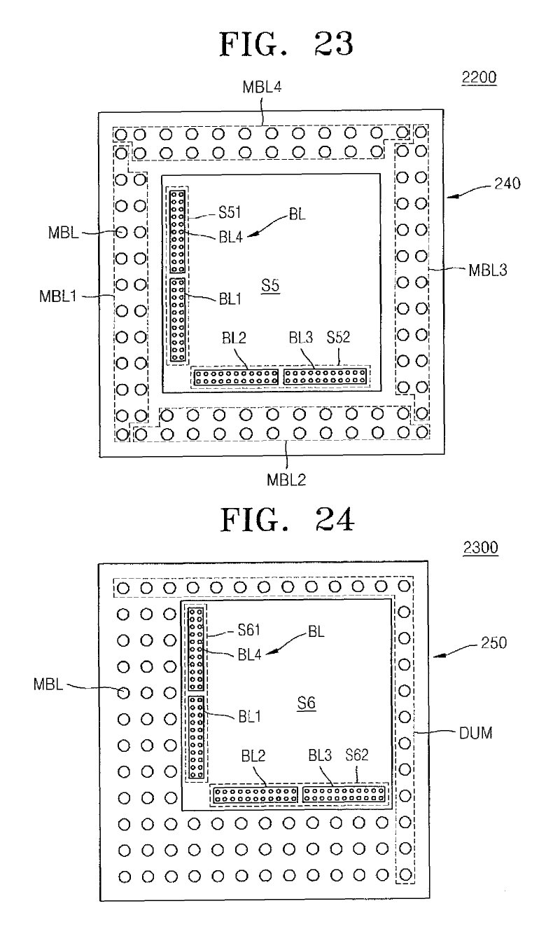

As illustrated in FIG. 24, in the semiconductor stack package apparatus 2300 according to an exemplary embodiment, a bump land BL of the lower substrate 250, which corresponds to the bump BU of the lower semiconductor chip 210, may include a first interface unit BL1, a second interface unit BL2, a third interface unit BL3 and a fourth interface unit BL4. The first interface unit BL1 is a physical terminal that is electrically connected to an intermediate ball land unit corresponding to the first semiconductor chip 111 of the upper semiconductor chip 110, and which is disposed on a first end S61 of a lower semiconductor chip corresponding region Sb. The fourth interface unit BL4 is a physical terminal that is electrically connected to an intermediate ball land unit corresponding to the fourth semiconductor chip 114 of the upper semiconductor chip 110, and which is disposed together with the first interface unit BL1 on the first end S61 of the lower semiconductor chip corresponding region S6. The second interface unit BL2 is a physical terminal that is electrically connected to an intermediate ball land unit corresponding to the second semiconductor chip 112 of the upper semiconductor chip 110, and which is disposed on a second end S62 of the lower semiconductor chip corresponding region S6. The third interface unit BL3 is a physical terminal that is electrically connected to an intermediate ball land unit corresponding to the third semiconductor chip 113 of the upper semiconductor chip 110, and which is disposed together with the second interface unit BL2 on the second end S62 of the lower semiconductor chip corresponding region S6. In an intermediate ball land MBL of the lower substrate 250, a dummy ball land unit DUM in which dummy solder balls are attached in one or more directions (e.g., two neighboring side directions, as shown in FIG. 24) with respect to the lower substrate 250 may be formed. The dummy solder balls and the dummy ball land unit DUM allow the lower semiconductor chip corresponding region S6 to be disposed relatively in a center area of the lower substrate 250, and the dummy solder balls and the dummy ball land unit DUM may protect the lower semiconductor chip 210 from, for example, an external force, various types of shocks, or electrical interference.

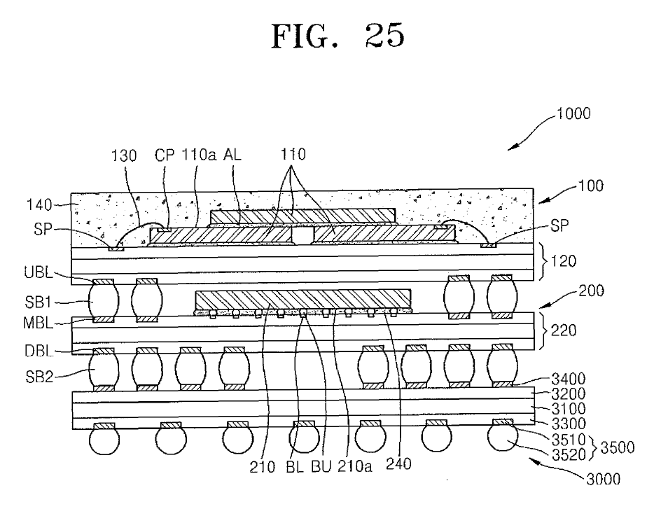

FIG. 25 is a cross-sectional view illustrating the semiconductor stack package apparatus 1000 mounted on a board substrate 3000, according to an exemplary embodiment of the inventive concept.

The semiconductor stack package apparatus 1000 of FIG. 25 includes an upper semiconductor package 100, a lower semiconductor package 200, and the board substrate 3000. The upper semiconductor package 100 and the lower semiconductor package 200 of FIG. 25 may have similar structures as the upper semiconductor package 100 and the lower semiconductor package 200 described with reference to FIGS. 1 through 4. Thus, detailed descriptions of the upper semiconductor package 100 and the lower semiconductor package 200 may be omitted.

The upper semiconductor package 100 and the lower semiconductor package 200 may be mounted on the board substrate 3000. The board substrate 3000 may include a body layer 3100, an upper protective layer 3200, a lower protective layer 3300, an upper pad 3400, and a connecting member 3500 including a plurality of ball lands 3510 and solder balls 3520. A plurality of wiring patterns may be formed on the body layer 3100. The upper protective layer 3200 and the lower protective layer 3300 may protect the body layer 3100 and may be solder-resist. The board substrate 3000 may be standardized.

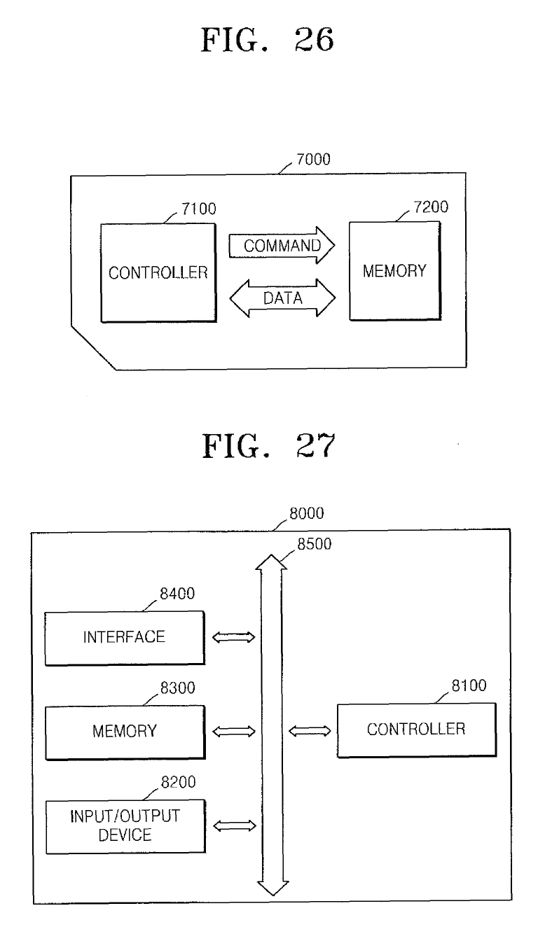

FIG. 26 is a block diagram illustrating a memory card 7000 including one of the semiconductor stack package apparatuses described above, according to an exemplary embodiment of the inventive concept.

As illustrated in FIG. 26, a controller 7100 and a memory 7200 exchange an electrical signal in the memory card 7000. For example, when the controller 7100 outputs a command, the memory 7200 may transmit data. The controller 7100 and/or the memory 7200 may include one of the semiconductor stack package apparatuses according to the exemplary embodiments described above. The memory 7200 may include, for example, a memory array or a memory array bank.

The memory card 7000 may be used in memory devices including, for example, a memory stick card, a smart media card (SM), a secure digital card (SD), a mini secure digital card (mini SD), or a multimedia card (MMC).

FIG. 27 is a block diagram illustrating an electronic system 8000 including one of the semiconductor stack package apparatuses described above, according to an exemplary embodiment of the inventive concept.

As illustrated in FIG. 27, the electronic system 8000 includes a controller 8100, an input/output device 8200, a memory 8300, and an interface 8400. The electronic system 8000 may be, for example, a mobile system or a system for transmitting or receiving information. The mobile system may include, for example, a personal digital assistant (PDA), a portable computer, a tablet computer, a wireless phone, a mobile phone, a digital music player, or a memory card.

The controller 8100 may execute a program and may control the electronic system 8000. For example, the controller 8100 may be a microprocessor, a digital signal processor, or a microcontroller. The input/output device 8200 may input or output data to or from the electronic system 8000.

The electronic system 8000 may be connected to an external device such as, for example, a personal computer or a network, and may exchange data with the external device using the input/output device 8200. The input/output device 8200 may be, for example, a keypad, a keyboard, or a display. The memory 8300 may store code and/or data used to operate the controller 8100, and/or may store data processed by the controller 8100. The controller 8100 and the memory 8300 may include one of the semiconductor stack package apparatuses according to the exemplary embodiments described above. The interface 8400 may function as a data transmission path between the electronic system 8000 and the external device. The controller 8100, the input/output device 8200, the memory 8300, and the interface 8400 may communicate with each other via a bus 8500.

The electronic system 8000 may be used in, for example, a mobile phone, an MPEG-1 Audio Layer-3 (MP3) player, a navigation system, a portable multimedia player (PMP), a solid state disk (SSD), or household appliances.

While the inventive concept has been particularly shown and described with reference to exemplary embodiments thereof, it will be understood that various changes in form and detail may be made therein without departing from the spirit and scope of the inventive concept as defined by the following claims.

What is claimed is:

1. A semiconductor stack package apparatus, comprising:
an upper semiconductor package, comprising:
an upper semiconductor chip comprising a chip pad formed on an active surface of the upper semiconductor chip;
an upper substrate comprising a substrate pad formed on a top surface of the upper substrate, and an upper ball land formed on a bottom surface of the upper substrate and attached to an intermediate solder ball; and
a wire electrically connecting the chip pad and the substrate pad; and
a lower semiconductor package, comprising:
a lower semiconductor chip comprising a bump farmed on an active surface of the lower semiconductor chip; and
a lower substrate comprising a bump land formed on a top surface of the lower substrate in an area corresponding to the bump, an intermediate ball land formed on the top surface of the lower substrate in an area corresponding to the intermediate solder ball, and a lower ball land formed on a bottom surface of the lower substrate and attached to a lower solder ball.

2. The semiconductor stack package apparatus of claim 1, wherein the chip pad is one of a plurality of chip pads, and the plurality of chip pads are formed on one end of the upper semiconductor chip.

3. The semiconductor stack package apparatus of claim 1, wherein the chip pad is one of a plurality of chip pads, and the upper semiconductor chip comprises:
a first semiconductor chip comprising some of the plurality of chip pads formed on one end of the first semiconductor chip;
a second semiconductor chip comprising some of the plurality of chip pads formed on one end of the second semiconductor chip;
a third semiconductor chip comprising some of the plurality of chip pads formed on one end of the third semiconductor chip; and
a fourth semiconductor chip comprising some of the plurality of chip pads formed on one end of the fourth semiconductor chip.

4. The semiconductor stack package apparatus of claim 3, wherein the first semiconductor chip is mounted on the top surface of the upper substrate, the second semiconductor chip is stacked on a top surface of the first semiconductor chip, the third semiconductor chip is stacked on a top surface of the second semiconductor chip, and the fourth semiconductor chip is stacked on a top surface of the third semiconductor chip.

5. The semiconductor stack package apparatus of claim 3, wherein the first semiconductor chip and the third semiconductor chip are mounted on the top surface of the upper substrate, and the second semiconductor chip and the fourth semiconductor chip are stacked on a top surface of the first semiconductor chip and the third semiconductor chip.

6. The semiconductor stack package apparatus of claim 3, wherein
the second semiconductor chip is stacked on the first semiconductor chip and the fourth semiconductor chip is stacked on the third semiconductor chip,
the chip pads of the first semiconductor chip and the chip pads of the second semiconductor chip extend in a substantially same direction,
the chip pads of the third semiconductor chip and the chip pads of the fourth semiconductor chip extend in a substantially same direction, and
the chip pads of the first and second semiconductor chips are substantially parallel with or substantially perpendicular to the chip pads of the third and fourth semiconductor chips.

7. The semiconductor stack package apparatus of claim 1, wherein the chip pad is one of a plurality of chip pads, and the upper semiconductor chip comprises:
a first semiconductor chip comprising some of the plurality of chip pads formed on opposing ends of the first semiconductor chip;
a second semiconductor chip comprising some of the plurality of chip pads formed on opposing ends of the second semiconductor chip;
a third semiconductor chip comprising some of the plurality of chip pads formed on opposing ends of the third semiconductor chip; and
a fourth semiconductor chip comprising some of the plurality of chip pads formed on opposing ends of the fourth semiconductor chip,
wherein the first semiconductor chip and the third semiconductor chip are mounted on the top surface of the upper substrate, and the second semiconductor chip and the fourth semiconductor chip are mounted on a top surface of the first semiconductor chip and the third semiconductor chip.

8. The semiconductor stack package apparatus of claim 7, wherein an inner wire bonding space is formed between the first semiconductor chip and the third semiconductor chip, and between the second semiconductor chip and the fourth semiconductor chip.

9. The semiconductor stack package apparatus of claim 1, wherein the chip pad is one of a plurality of chip pads, and the upper semiconductor chip comprises:
a first semiconductor chip comprising some of the plurality of chip pads formed on one end of the first semiconductor chip;
a second semiconductor chip comprising some of the plurality of chip pads formed on two opposing ends of the second semiconductor chip;
a third semiconductor chip comprising some of the plurality of chip pads formed on one end of the third semiconductor chip; and
a fourth semiconductor chip comprising some of the plurality of chip pads formed on two opposing ends of the fourth semiconductor chip,
wherein the second semiconductor chip is stacked on the first semiconductor chip, the fourth semiconductor chip is stacked on the third semiconductor chip, and the chip pads of the first and second semiconductor chips extend in direction substantially parallel with the chip pads of the third and fourth semiconductor chips.

10. The semiconductor stack package apparatus of claim 9, wherein an inner wire bonding space is formed between the second semiconductor chip and the fourth semiconductor chip.

11. The semiconductor stack package apparatus of claim 1, wherein the chip pad is one of a plurality of chip pads, and the upper semiconductor chip comprises:
a first semiconductor chip comprising some of the plurality of chip pads formed on one end of the first semiconductor chip;
a second semiconductor chip comprising some of the plurality of chip pads formed on two opposing ends of the second semiconductor chip;
a third semiconductor chip comprising some of the plurality of chip pads formed on one end of the third semiconductor chip; and
a fourth semiconductor chip comprising some of the plurality of chip pads formed on two opposing ends of the fourth semiconductor chip,
wherein the second semiconductor chip is stacked on the first semiconductor chip, the fourth semiconductor chip is stacked on the third semiconductor chip, and the chip pads of the first and second semiconductor chips extend in a direction substantially perpendicular to the chip pads of the third and fourth semiconductor chips.

12. The semiconductor stack package apparatus of claim 1, wherein the upper semiconductor chip comprises:
a plurality of DQ chip pads and a plurality of CA chip pads, wherein the DQ chip pads are configured to input and output data signals, and the CA chip pads are configured to input and output address signals and power signals;
a first semiconductor chip comprising some of the plurality of DQ chip pads disposed on one end of the first semiconductor chip, and some of the plurality of CA chip pads disposed on an opposing end of the first semiconductor chip;
a second semiconductor chip comprising some of the plurality of DQ chip pads disposed on one end of the second semiconductor chip, and some of the plurality of CA chip pads disposed on an opposing end of the second semiconductor chip;
a third semiconductor chip comprising some of the plurality of DQ chip pads disposed on one end of the third semiconductor chip, and some of the plurality of CA chip pads disposed on an opposing end of the third semiconductor chip; and
a fourth semiconductor chip comprising some of the plurality of DQ chip pads disposed on one end of the fourth semiconductor chip, and some of the plurality of CA chip pads disposed on an opposing end of the fourth semiconductor chip,
wherein the first semiconductor chip is mounted on the top surface of the upper substrate, the second semiconductor chip is stacked on a top surface of the first semiconductor chip, the third semiconductor chip is stacked on a top surface of the second semiconductor chip, and the fourth semiconductor chip is stacked on a top surface of the third semiconductor chip, and
wherein the first and second semiconductor chips are aligned with each other, the second semiconductor chip is transverse to the third semiconductor chip, and the third and fourth semiconductor chips are aligned with each other.

13. The semiconductor stack package apparatus of claim 1, wherein the upper substrate or the lower substrate comprises:
a first redistribution layer electrically connected to the substrate pad or the intermediate ball land;
a second redistribution layer electrically connected to the first redistribution layer, and one of the upper ball land or the lower ball land; and
a metal core layer formed between the first redistribution layer and the second redistribution layer.

14. The semiconductor stack package apparatus of claim 1, wherein the bump land of the lower substrate corresponds to the bump of the lower semiconductor chip, and comprises:
a first interface unit electrically connected to a first semiconductor chip of the upper semiconductor chip, and disposed on a first end of a lower semiconductor chip corresponding region;
a second interface unit electrically connected to a second semiconductor chip of the upper semiconductor chip, and disposed on a second end of the lower semiconductor chip corresponding region;
a third interface unit electrically connected to a third semiconductor chip of the upper semiconductor chip, and disposed on a third end of the lower semiconductor chip corresponding region; and
a fourth interface unit electrically connected to a fourth semiconductor chip of the upper semiconductor chip, and disposed on a fourth end of the lower semiconductor chip corresponding region.

15. The semiconductor stack package apparatus of claim 1, wherein the bump land of the lower substrate corresponds to the bump of the lower semiconductor chip, and comprises:
a first interface unit electrically connected to a first semiconductor chip of the upper semiconductor chip, and disposed on a first end of a lower semiconductor chip corresponding region;
a fourth interface unit electrically connected to a fourth semiconductor chip of the upper semiconductor chip, and disposed on the first end of the lower semiconductor chip corresponding region;
a second interface unit electrically connected to a second semiconductor chip of the upper semiconductor chip, and disposed on a second end of the lower semiconductor chip corresponding region; and
a third interface unit electrically connected to a third semiconductor chip of the upper semiconductor chip, and disposed on the second end of the lower semiconductor chip corresponding region.

16. The semiconductor stack package apparatus of claim 1, wherein the intermediate ball land comprises a dummy ball land, and the dummy ball land is attached to dummy solder balls.

17. The semiconductor stack package apparatus of claim 1, further comprising an encapsulation member disposed on the active surface of the upper semiconductor chip.

18. A semiconductor package, comprising:
a substrate comprising a plurality of substrate pads;
a first semiconductor chip disposed on the substrate, and comprising a plurality of chip pads disposed on one end of the first semiconductor chip;
a second semiconductor chip disposed on the first semiconductor chip, and comprising a plurality of chip pads disposed on one end of the second semiconductor chip;
a third semiconductor chip disposed on the substrate, and comprising a plurality of chip pads disposed on one end of the third semiconductor chip;
a fourth semiconductor chip disposed on the third semiconductor chip, and comprising a plurality of chip pads disposed on one end of the fourth semiconductor chip; and
a plurality of wires electrically connecting the chip pads of the first through fourth semiconductor chips to the plurality of substrate pads.

19. The semiconductor package of claim 18, wherein the chip pads of the first and second semiconductor chips extend in a direction substantially parallel with the chip pads of the third and fourth semiconductor chips.

20. The semiconductor package of claim 19, wherein the chip pads of the first and second semiconductor chips extend in a direction substantially perpendicular to the chip pads of the third and fourth semiconductor chips.
